(19) United States
(12) Patent Application Publication
(10) Pub. No.: US 2013/0039515 A1
(43) Pub. Date: Feb. 14, 2013

(54) SPEAKER COMPONENT, SPEAKER USING SAME, ELECTRONIC APPARATUS, AND MOVING MEANS

(71) Applicants: Yohei Jin, Mie (JP); Yoshimichi Kajihara, Mie (JP)

(72) Inventors: Yohei Jin, Mie (JP); Yoshimichi Kajihara, Mie (JP)

(73) Assignee: PANASONIC CORPORATION, Kadoma-shi, Osaka (JP)

(21) Appl. No.: 13/642,297

(22) PCT Filed: Jun. 24, 2011
(86) PCT No.: PCT/JP2011/003610

§ 371 Date: Oct. 19, 2012

(30) Foreign Application Priority Data
Jun. 28, 2010 (JP) 2010-145848
Sep. 9, 2010 (JP) 2010-201646

(51) Int. Cl. H04R 1/00; H04R 7/02; D21H 17/63; H03F 99/00

(52) U.S. Cl. 381/120; 381/407; 381/400; 181/169; 162/159

(57) ABSTRACT

Provided is a speaker diaphragm or a speaker voice coil bobbin manufactured by a papermaking method and including metal hydroxide by at least an amount of 30 wt % or greater. With this, it is possible to improve rigidity and achieve favorable acoustic quality by an effect of mixing metal hydroxide. Moreover, it is possible to provide a paper-made diaphragm or a voice coil bobbin with flame retardancy without increasing weight or cost.

### TECHNICAL FIELD

The present invention relates to a speaker component used in various acoustic and video equipments and a speaker using such a speaker component.

### BACKGROUND ART

In recent years, paper-made diaphragms that can be mass-produced at a low cost have been mainly used as speaker diaphragms for home use and on-vehicle audio apparatuses.

Further, such a paper-made diaphragm has a low specific gravity and a high internal loss, and therefore is superior in terms of acoustic quality. On the other hand, it has been pressed forward to reduce thickness and increase maximum input power as a user-side trend, and providing flame retardancy is increasingly required in order to reduce the risk of heat generation, ignition from a voice coil, and catch fire from different members.

Examples of a conventional flame retarding technology for approaching to this problem include methods described below.

There are technical methods of, during pulp molding, providing pulp with flame retardancy by causing the pulp to contain diatomaceous earth, mixing highly heat-resistant chemical fiber, and providing a diaphragm with flame retardancy by adding inorganic fiber, organic fiber, or inorganic powder to fine wood pulp and then impregnating the fine wood pulp with heat resistant impregnant.

It should be noted that known prior art documents relating to this technology include PTLs 1, 2, and 3, for example.

In general, paper-made diaphragms are advantageous in terms of low production costs as compared to resin diaphragms and metallic diaphragms. In addition, the paper-made diaphragms are superior in terms of high internal losses and low specific gravities, and advantageous in improving acoustic quality.

On the other hand, there is also a problem that such paper-made diaphragms made of cellulose as a main raw material are disadvantageous in product safety, as being easily burned and poor in flame retardancy.

For this reason, in order to provide a paper-made diaphragm with flame retardancy, means of adding high heat resistant organic fiber or inorganic fiber, and means of providing a treatment as secondary processing using a flame retardant impregnant have been contrived.

However, the material cost of such means is high, and the production cost also increases as the number of steps increases by providing secondary processing such as an impregnation treatment. Moreover, there is a problem that impregnating a diaphragm results in an increase of the weight of the diaphragm, and may result in a decrease of the sound pressure.

Further, in recent years, there is a growing trend that high input power is applied to speakers used in various acoustic equipment and video equipment.

For this reason, a voice coil bobbin having a superior heat resistance is demanded, as Joule heat is generated in the voice coil bobbin and the temperature increases due to accumulation of the heat.

On the other hand, it has been pressed forward to reduce thickness and increase maximum input power as a user-side trend, and an improvement of heat resistance and providing flame retardancy are increasingly required in order to reduce the risk of heat generation, ignition from the voice coil, and catch fire from a different member.

In response to such a demand, currently, tubular bobbins made of such as kraft paper and aluminum as well as bobbins made of a resin film are widely used. Further, it is commonly employed to provide a highly heat resistant bobbin by performing an impregnation treatment and a secondary treatment to paper, and to use a polyimide resin having superior heat resistance and proccessability.

It should be noted that known prior art documents relating to this technology include PTLs 4, 5, and 6, for example. Paper-made voice coil bobbins are widely used as being lightweight and inexpensive.

However, there is a problematic point that such paper-made voice coil bobbins are low in heat resistance, easily burned, and poor in heat releasing property. This involves a problem that a fire may break out from the voice coil bobbin in a case in which an abnormal current flows through a speaker or in which a peripheral portion of the speaker is abnormally heated.

Moreover, a voice coil bobbin made of a paper material is poor in moisture resistance and water resistance, and strength of the paper material that has absorbed moisture or water decreases as combination between fibers of such paper material becomes weaker. Accordingly, there is a problematic point that the voice coil bobbin made of a paper material is not suitable for a speaker installed in a severe environment of usage where water may directly pour to the speaker or in a highly humid environment, for example, such as an on-vehicle speaker.

Further, a voice coil bobbin made of paper has a weakness of low rigidity. As the rigidity provided for pulp as a raw material of paper is not sufficient, in order to solve this weakness, an inorganic additive such as calcium carbonate and titanium dioxide is filled over a surface of the pulp fiber and between fibers. Such an inorganic filling material is highly rigid itself, but mostly just adsorbed over the surface of the fiber, and therefore have a weakness that the inorganic filling material falls out during pulp refining and does not work very effectively in order to provide rigidity for paper.

Further, a voice coil bobbin made of a metallic foil or a polyimide film is expensive. Moreover, in particular when the voice coil bobbin is made of a metallic foil, there is a problem to be solved that acoustic reproduction quality is not very good as a vibration system is brought into an overdamped state.

Moreover, while a metallic voice coil bobbin is superior in heat resistance and moisture resistance, it also has a problem that a sound pressure level of the speaker is decreased as being heavy weighted.

Further, while a voice coil bobbin using a metallic foil such as aluminum in order to solve the problematic points of the paper material is superior in heat resistance, its specific gravity is greater than that of the paper material or the resin, and has good heat conductivity. Accordingly, heat generated from the voice coil is transmitted all over the bobbin, and there is a possibility that other components assembled to the voice coil such as a diaphragm, a center cap, and a damper, as well as an adhesive agent that fixedly attaches these components are dissolved or ignited. Therefore, high heat resistance is also demanded for the material of these components and such.

A polyimide resin is a highly heat resistant resin, but it has a problem in terms that there is a case in which heat is accumulated and the temperature becomes high as its heat conductivity is low. While heat resistant resin films made of such as polyimide and polyamide are used in order to solve such a problematic point of the paper material, there is other problematic points of high cost and poor adhesiveness, as well as that it dissolves at a high temperature.

### CITATION LIST

### Patent Literature

PTL 1: Unexamined Japanese Patent Publication No. 2010-31136
PTL 2: Unexamined Japanese Patent Publication No. H04-367197
PTL 3: Unexamined Japanese Patent Publication No. 2001-169387
PTL 4: Unexamined Japanese Patent Publication No. H06-70396
PTL 5: Unexamined Japanese Patent Publication No. H07-11099
PTL 6: Unexamined Japanese Patent Publication No. H06-121388

### SUMMARY OF THE INVENTION

A speaker component according to the present invention is a speaker component manufactured by a papermaking method and includes metal hydroxide by at least an amount of 30 wt % or greater.

With this configuration, by mixing metal hydroxide, it is possible to provide flame retardancy for the speaker component such as a diaphragm and a voice coil bobbin, and to realize the speaker component having high acoustic quality at a low cost.

### BRIEF DESCRIPTION OF DRAWINGS

FIG. 1 is a perspective view of a speaker diaphragm according to a first exemplary embodiment of the present invention.

FIG. 2 is a cross-sectional view of a speaker according to a second exemplary embodiment of the present invention.

FIG. 3 is an external view of a mini component system according to a third exemplary embodiment of the present invention.

FIG. 4 is a cross-sectional view of a vehicle according to a fourth exemplary embodiment of the present invention.

FIG. 5 is a perspective view of a voice coil bobbin according to a fifth exemplary embodiment of the present invention.

FIG. 6 is a cross-sectional view of a speaker according to a sixth exemplary embodiment of the present invention.

FIG. 7 is an external view of an electronic apparatus according to a seventh exemplary embodiment of the present invention.

FIG. 8 is a cross-sectional view of a vehicle according to an eighth exemplary embodiment of the present invention.

### DESCRIPTION OF EMBODIMENTS

### First Exemplary Embodiment

Hereinafter, a speaker diaphragm is described as one embodiment of a speaker component according to the present invention.

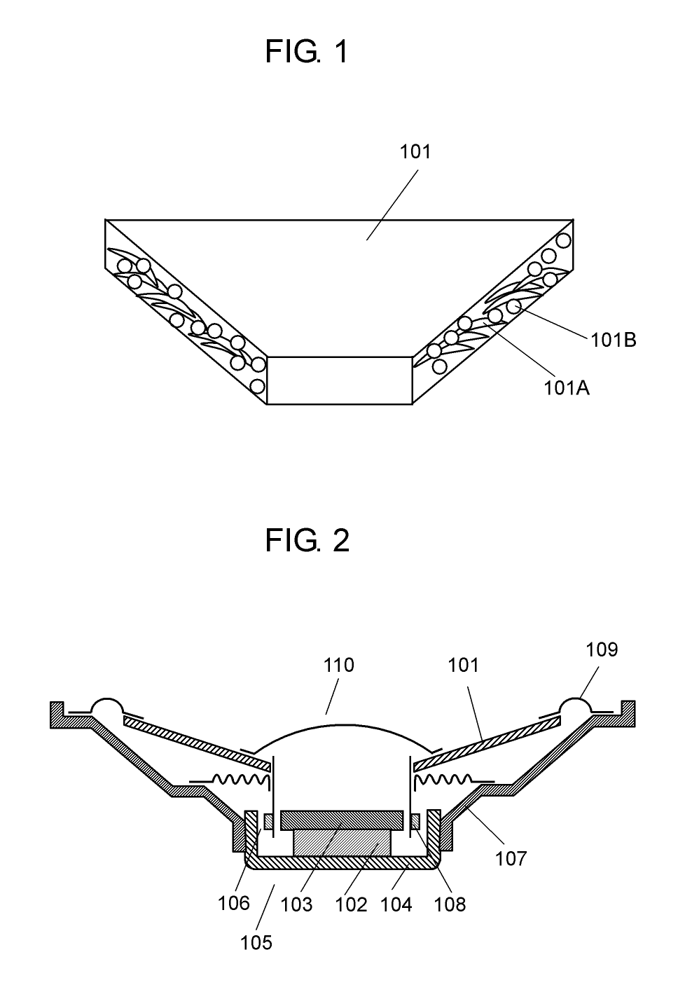

FIG. 1 is a perspective view of a speaker diaphragm according to a first exemplary embodiment of the present invention.

As illustrated in FIG. 1, desired flame retardancy can be obtained for speaker diaphragm 101 by adding metal hydroxide 101B to natural fiber 101A by at least an amount of 30 wt % or greater.

In order to achieve further superior flame retardancy, it is desirable to add metal hydroxide by an amount from 50 wt % to 90 wt %. If the amount of metal hydroxide that has been added is less than 30 wt %, it is difficult to obtain desired flame retardancy, and not very effective.

On the other hand, adding more than 90 wt % of metal hydroxide causes poor dispersion of the metal hydroxide when mixing and a decrease of strength of speaker diaphragm 101. Examples of metal hydroxide used here include aluminum hydroxide and magnesium hydroxide.

When heated, metal hydroxide is rapidly dehydrated and resolved, and exhibits a large endothermic reaction. As crystal water produced at this time extinguishes fire, the material itself has a characteristic of providing a self-extinguishing property.

A non-wood material can be used as a papermaking material in place of wood pulp. In this case, it is possible to use various kinds of fiber such as bamboo, kenaf, jute, bagasse, and hemp. In addition, by increasing a proportion of the non-wood material as a papermaking material, the cut of timber can be reduced and it is possible to provide a diaphragm having a small impact on the environment.

Among a number of kinds of non-wood fiber, bamboo fiber causes fewer environmental problems and can be sustainably supplied, as bamboo grows fast. Moreover, bamboo fiber is eco-friendly as it can be disposed by incineration instead of landfilling as in the case of inorganic fiber such as glass fiber.

When using bamboo fiber as a papermaking material, it is desirable to use bamboo fiber obtained from bamboos aged one year or older. In general, bamboos grow in 50 days after birth and then grow to stabilize its substance, and it is possible to obtain stable substance after about one year or more passes. Accordingly, it is possible to obtain a desired characteristic for an acoustic member. However, no matter how fast-growing bamboos are, if logging within the first year after birth is continued, the bamboo forest cannot grow stably and the bamboo ecosystem may possibly be disturbed.

It is desirable that an amount of bamboo fiber added to speaker diaphragm 101 be 70 wt % or smaller. If the added amount of bamboo fiber is 70 wt % or smaller, it is possible to obtain a diaphragm having high rigidity and a high internal loss, and therefore it is possible to obtain a diaphragm capable of producing rich sound of high acoustic quality. On the other hand, if the amount of bamboo fiber added to speaker diaphragm 101 is greater than 70 wt %, an amount that metal hydroxide is blended relatively decreases, and it is not possible to obtain desired flame retardancy.

Fiber that is beat to a degree of beating based on Canadian standard freeness ranges from 200 ml to 700 ml inclusive has rigidity suitable as a framework, and less susceptible to poor dispersion during papermaking. Here, if the degree of beating based on Canadian standard freeness is lower than 200 ml, speed of water filtration during papermaking reduces, and productivity significantly decreases. On the other hand, if the degree of beating based on Canadian standard freeness is higher than 700 ml, a magnitude of entanglement between fibers decreases, and it is difficult to obtain a desired effect. Examples of a method of refining bamboo fiber include a disk refiner and a beater.

If the bamboo fiber is natural fiber having a fiber length from 0.8 mm to 3 mm inclusive, a reinforcing effect as a framework can be enough expected, and it is possible to reduce paper-making unevenness when mixed. Here, if the fiber length of the bamboo fiber is shorter than 0.8 mm, the magnitude of entanglement between fibers becomes insufficient and strength of a papermade preform is not sufficient, and it is not possible to obtain a sufficient characteristic. Further, when mixing metal hydroxide, if the fiber length is short, a proportion of metal hydroxide fixed to the fiber becomes lower, and thus the flame retardancy decreases. On the other hand, if the fiber length of the bamboo fiber is longer than 3 mm, poor dispersion occurs when mixing, resulting in reduced dispersibility and poor appearance of a molding product.

By molding speaker diaphragm 101 so as to have a density from 0.30 g/cm³ to 0.90 g/cm³ inclusive, it is possible to mold speaker diaphragm 101 without fear of damaging softness and lightness that paper originally has. Here, if the density of speaker diaphragm 101 is smaller than 0.30 g/cm³, the strength significantly reduces and therefore an abnormal noise such as flutter echo in a high-frequency area is produced due to insufficient strength. On the other hand, if the density of speaker diaphragm 101 is greater than 0.90 g/cm³, the specific gravity becomes as much as that of a resin diaphragm, and therefore it is not possible to exhibit superiority in lightness as a feature of the paper-made diaphragms, resulting in deterioration of the characteristic such as reduction of the sound pressure.

If an amount of content of lignin in the bamboo fiber is 25 wt % or smaller, it is possible to achieve acoustic quality of rich sound due to a high internal loss of lignin. On the other hand, if the amount of content of lignin is greater than 25 wt %, adhesion between the bamboo fibers is prevented as a surface of the bamboo fiber contains too much lignin, and it is difficult to mold a diaphragm due to insufficient strength when molding as a diaphragm.

Furthermore, as means for effectively improving the acoustic quality, it is desirable to add bamboo fiber beat to a microfibrillated state as a subordinate material. It is desirable that a proportion of an additive amount of the bamboo fiber beat to the microfibrillated state to the bamboo fiber as a whole be from 5 wt % to 20 wt % inclusive. If the proportion of the additive amount of the bamboo fiber beat to the microfibrillated state ranges from 5 wt % to 20 wt % inclusive, it is possible to obtain a reinforcing effect effective for a binder between fibers. If the proportion of the additive amount of the bamboo fiber beat to the microfibrillated state is smaller than 5 wt %, it is not possible to obtain a sufficient reinforcing effect as the additive amount is not enough. On the other hand, if the proportion of the additive amount of the bamboo fiber beat to the microfibrillated state is greater than 20 wt %, dispersion becomes poor during papermaking, and appearance of the diaphragm becomes poor.

Further, in general, as water filtration of fiber beat to the microfibrillated state is low, time required until this fiber is dehydrated in a papermaking step becomes extremely long, and this significantly increases the production cost. Therefore, it is desirable that a suitable additive amount of the bamboo fiber beat to the microfibrillated state be from 5 wt % to 20 wt % inclusive.

Further, the size of the bamboo fiber beat to the microfibrillated state is enough fined if its fiber length is 0.8 mm or smaller, and the magnitude of entanglement between fibers is enhanced to obtain a desired reinforcing effect. On the other hand, if the fiber length is greater than 0.8 mm, the bamboo fiber is not sufficiently beat, and the magnitude of entanglement between fibers is insufficient and the reinforcing effect is poor.

Furthermore, it is desirable that the degree of beating of the bamboo fiber fined to the microfibrillated state described above be 200 ml or smaller. If the degree of beating is 200 ml or smaller, it is possible to obtain an extremely high reinforcing effect as compared to normal bamboo fiber, as well as superior cost-effectiveness even with a small additive amount. If the degree of beating is greater than 200 ml, this fiber has a characteristic comparable to that of normal bamboo fiber, and it is not possible to obtain a reinforcing effect as microfibril fiber.

Furthermore, it is possible to improve the flame retardancy and adjust the acoustic quality by blending a reinforcing material as needed.

As the reinforcing material, inorganic fiber or metallic fiber can also be added as reinforcement fiber and a conditioning material of the acoustic quality.

Examples of the inorganic fiber include glass fiber, carbon fiber, and ceramic fiber. Further, examples of the metallic fiber include stainless steel fiber.

It is desirable that an additive amount of glass fiber be from 5 wt % to 40 wt % inclusive, and it is possible to further improve the flame retardancy of the paper-made diaphragm by mixing the glass fiber by this additive amount. Further, as the glass fiber is rigid, it is possible to increase the rigidity of the paper-made diaphragm by mixing. If the additive amount of the glass fiber is smaller than 5 wt %, it is not possible to obtain such effects as a flame-retardant effect and an increased rigidity. If the additive amount of the glass fiber is greater than 40 wt %, many disadvantages are presented such as the paper-making unevenness, the poor appearance, and an increased specific gravity.

It is desirable that an additive amount of carbon fiber be from 5 wt % to 40 wt % inclusive, and it is possible to further improve the flame retardancy of the paper-made diaphragm by mixing the carbon fiber by this additive amount. Further, as the carbon fiber is rigid, it is possible to increase the rigidity of the paper-made diaphragm by mixing. If the additive amount of the carbon fiber is smaller than 5 wt %, it is not possible to obtain such effects as the flame-retardant effect and the increased rigidity. If the additive amount of the carbon fiber is greater than 40 wt %, many disadvantages are presented such as the paper-making unevenness, the poor appearance, and the increased specific gravity.

It is desirable that an additive amount of ceramic fiber be from 5 wt % to 40 wt % inclusive, and it is possible to further improve the flame retardancy of the paper-made diaphragm by mixing the ceramic fiber by this additive amount. Further, as the ceramic fiber is rigid, it is possible to increase the rigidity of the paper-made diaphragm by mixing. If the additive amount of the ceramic fiber is smaller than 5 wt %, it is not possible to obtain such effects as the flame-retardant effect and the increased rigidity. If the additive amount of the ceramic fiber is greater than 40 wt %, many disadvantages are presented such as the paper-making unevenness, the poor appearance, and the increased specific gravity.

It is desirable that an additive amount of stainless steel fiber be from 5 wt % to 40 wt % inclusive, and it is possible to further improve the flame retardancy of the paper-made diaphragm by mixing the stainless steel fiber by this additive amount. Further, as the stainless steel fiber is rigid, it is possible to increase the rigidity of the paper-made diaphragm by mixing. If the additive amount of the stainless steel fiber is smaller than 5 wt %, it is not possible to obtain such effects as the flame-retardant effect and the increased rigidity. If the additive amount of the stainless steel fiber is greater than 40 wt %, many disadvantages are presented such as the paper-making unevenness, the poor appearance, and the increased specific gravity.

Furthermore, it is also possible to improve the flame retardancy and adjust the acoustic quality by blending a filler. As the filler, it is desirable to add calcium carbonate, talc, mica, or carbonized natural fiber.

It is desirable that an additive amount of calcium carbonate be from 5 wt % to 20 wt % inclusive, and it is possible to further improve the flame retardancy of the paper-made diaphragm by mixing calcium carbonate by this additive amount. Further, as calcium carbonate is rigid, it is possible to increase the rigidity of the paper-made diaphragm by mixing. If the additive amount of calcium carbonate is smaller than 5 wt %, it is not possible to obtain such effects as the flame-retardant effect and the increased rigidity. If the additive amount of calcium carbonate is greater than 20 wt %, many disadvantages are presented such as the paper-making unevenness, the poor appearance, and the increased specific gravity.

It is desirable that an additive amount of talc be from 5 wt % to 20 wt % inclusive, and it is possible to further improve the flame retardancy of the paper-made diaphragm by mixing talc by this additive amount. Further, as talc is rigid, it is possible to increase the rigidity of the paper-made diaphragm by mixing. If the additive amount of talc is smaller than 5 wt %, it is not possible to obtain such effects as the flame-retardant effect and the increased rigidity. If the additive amount of talc is greater than 20 wt %, many disadvantages are presented such as the paper-making unevenness, the poor appearance, and the increased specific gravity.

It is desirable that an additive amount of mica be from 5 wt % to 20 wt % inclusive, and it is possible to further improve the flame retardancy of the paper-made diaphragm by mixing mica by this additive amount. Further, as mica is rigid, it is possible to increase the rigidity of the paper-made diaphragm by mixing. If the additive amount of mica is smaller than 5 wt %, it is not possible to obtain such effects as the flame-retardant effect and the increased rigidity. If the additive amount of mica is greater than 20 wt %, many disadvantages are presented such as the paper-making unevenness, the poor appearance, and the increased specific gravity.

It is desirable that an additive amount of carbonized natural fiber be from 5 wt % to 20 wt % inclusive, and it is possible to further improve the flame retardancy of the paper-made diaphragm by mixing the carbonized natural fiber by this additive amount. Further, as the carbonized natural fiber is rigid, it is possible to increase the rigidity of the paper-made diaphragm by mixing. If the additive amount of the carbonized natural fiber is smaller than an additive amount of 5 wt %, it is not possible to obtain such effects as the flame-retardant effect and the increased rigidity. If the additive amount of the carbonized natural fiber is greater than 20 wt %, many disadvantages are presented such as the paper-making unevenness, the poor appearance, and the increased specific gravity. Further, the carbonized natural fiber includes numerous fine pores over its surface, reduction of the specific gravity and an improvement of the internal loss are also expected.

Further, it is also possible to improve the flame retardancy and the acoustic quality by combining a colorant, a waterproof agent, an impregnation treatment as the known art.

### Second Exemplary Embodiment

Hereinafter, speaker 110 employing speaker diaphragm 101 according to the first exemplary embodiment is described.

FIG. 2 is a cross-sectional view of a speaker according to a second exemplary embodiment of the present invention.

As illustrated in FIG. 2, in speaker 110, internal magnet type magnetic circuit 105 is configured by sandwiching magnetized magnet 102 between upper plate 103 and yoke 104. Frame 107 is coupled to yoke 104 of magnetic circuit 105. To a periphery portion of frame 107, an outer circumference of speaker diaphragm 101 according to the first exemplary embodiment is adhered via edge 109.

Then, one end of voice coil 108 is coupled to a center portion of speaker diaphragm 101, and the other end is coupled to magnetic gap 106 of magnetic circuit 105 so as to be fitted therein.

The above describes the speaker having an internal magnet type magnetic circuit. However, the present invention is not limited to such an example, and can be applied to a speaker having an external magnet type magnetic circuit.

With such a configuration, it is possible to provide a speaker capable of achieving flame retardancy, high acoustic quality, and cost reduction.

### Third Exemplary Embodiment

Hereinafter, mini component system 114 employing speaker 110 according to the second exemplary embodiment is described.

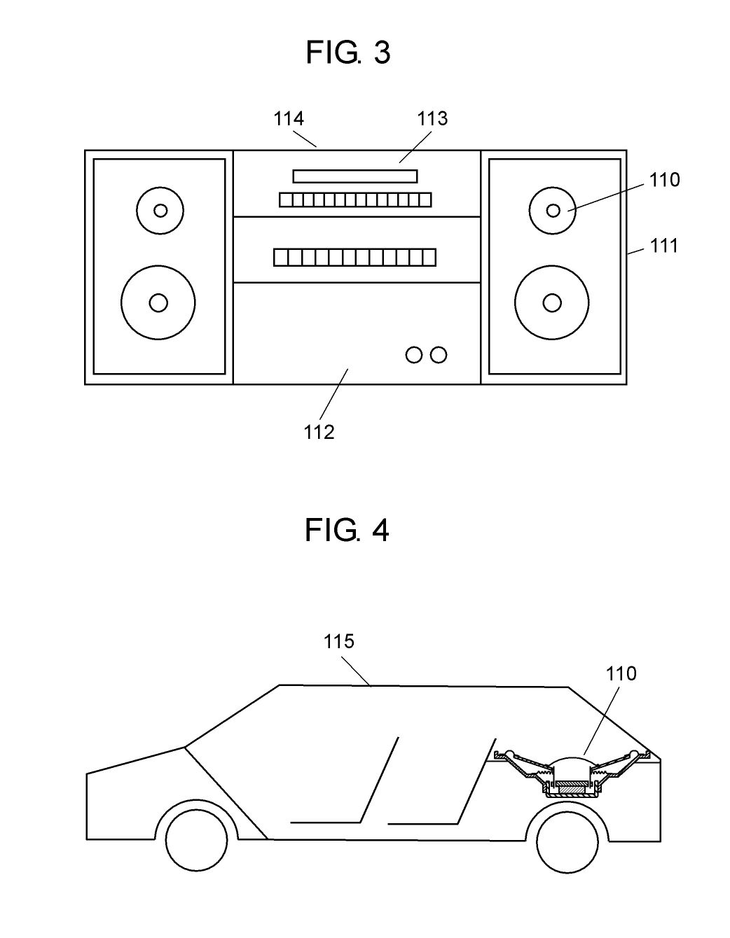

FIG. 3 is an external view of audio mini component system 114 as an electronic apparatus having speaker 110 built-in.

As illustrated in FIG. 3, mini component system 114 according to this embodiment includes enclosure 111 having speaker 110 assembled, amplifier 112 as means for amplifying electric signals inputted to speaker 110, and player 113 configured to output a source inputted to amplifier 112.

With such a configuration, mini component system 114 achieves flame retardancy, high acoustic quality, and cost reduction that cannot be conventionally achieved.

### Fourth Exemplary Embodiment

Hereinafter, vehicle 115 employing speaker 110 according to the second exemplary embodiment is described.

FIG. 4 is a cross-sectional view of vehicle 115 having speaker 110 built-in.

As illustrated in FIG. 4, vehicle 115 according to this embodiment utilizes speaker 110 as a component of car navigation or car audio sets by assembling speaker 110 to a rear tray or a front panel.

With such a configuration, vehicle 115 achieves flame retardancy and high acoustic quality that cannot be conventionally achieved.

### Fifth Exemplary Embodiment

Hereinafter, a speaker voice coil bobbin is described as one embodiment of a speaker component according to the present invention.

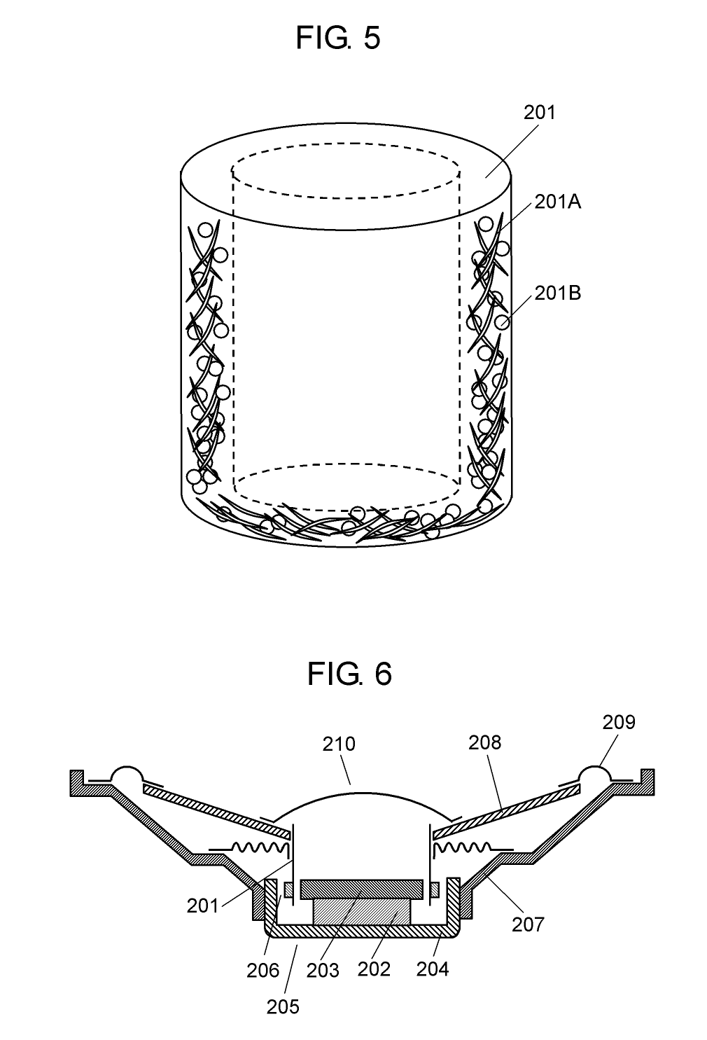

FIG. 5 is a perspective view of a voice coil bobbin according to a fifth exemplary embodiment of the present invention.

As illustrated in FIG. 5, speaker voice coil bobbin 201 is configured such that a material configured by natural fiber 201A containing metal hydroxide 201B by at least an amount of 30 wt % or greater is formed into a sheet shape by paper making and molded into a shape of a voice coil bobbin to provide a speaker voice coil bobbin.

As described above, desired flame retardancy can be obtained for speaker voice coil bobbin 201 by adding metal hydroxide 201B by at least an amount of 30 wt % or greater. Here, in order to achieve further superior flame retardancy, it is desirable to add metal hydroxide by an amount from 50 wt % to 90 wt %. If the amount of metal hydroxide that has been added is less than 30 wt %, it is difficult to obtain desired flame retardancy, and not very effective.

On the other hand, adding more than 90 wt % of metal hydroxide causes poor dispersion of the metal hydroxide when mixing and a decrease of strength of speaker voice coil bobbin 201. When heated, metal hydroxide is rapidly dehydrated and resolved, and exhibits a large endothermic reaction. As crystal water produced at this time extinguishes fire, the material itself has a characteristic of providing a self-extinguishing property.

In order to improve reliability in such as strength, it is desirable to use metal hydroxide subjected to a surface treatment using stearic acid, silane-based coupling agent, titanate-based coupling agent, or high-white based agent. Examples of metal hydroxide used here include aluminum hydroxide and magnesium hydroxide.

Further, it is desirable that metal hydroxide be in a granulated form. Metal hydroxide in a granulated form allows metal hydroxide to be efficiently dispersed and filled when forming into a sheet shape by paper making. It is desirable that an average grain diameter of aluminum hydroxide to be added be 100 μm or smaller. If an average grain diameter of aluminum hydroxide is 100 μm or smaller, it is possible to provide sufficient self-digesting property and to improve rigidity of the voice coil bobbin, and therefore acoustic quality can be improved. On the other hand, if the average grain diameter of aluminum hydroxide is larger than 100 μm, poor dispersion is caused during papermaking, often resulting in a decrease of an effect of the self-extinguishing property.

Moreover, it is desirable that a degree of purity of Al(OH)₃ as a main constituent in aluminum hydroxide to be added be 99% or higher. If the degree of purity of Al(OH)₃ as a main constituent in aluminum hydroxide to be added is 99% or lower, its effect is reduced and it is not possible to obtain a sufficient self-digesting property.

It is desirable that an average grain diameter of magnesium hydroxide to be added to speaker voice coil bobbin 201 be 100 μm or smaller. If an average grain diameter of magnesium hydroxide is 100 μm or smaller, it is possible to provide sufficient self-digesting property and to improve rigidity of the voice coil bobbin, and therefore acoustic quality can be improved. On the other hand, if the average grain diameter of magnesium hydroxide is larger than 100 μm, poor dispersion is caused during papermaking, often resulting in a decrease of an effect of the self-extinguishing property.

Moreover, it is desirable that a degree of purity of MgO as a main constituent in magnesium hydroxide to be added be 60% or higher. If the degree of purity of MgO as a main constituent in magnesium hydroxide to be added is 60% or lower, its effect is reduced and it is not possible to obtain a sufficient self-digesting property.

Next, a non-wood material can be used as a papermaking material in place of wood pulp, and it is possible to use various kinds of fiber such as bamboo, kenaf, jute, bagasse, and hemp in this case.

In addition, by increasing a proportion of the non-wood material as a papermaking material, the cut of timber can be reduced and it is possible to provide a voice coil bobbin having a small impact on the environment.

Among a number of kinds of non-wood fiber, bamboo fiber causes fewer environmental problems and can be sustainably supplied, as bamboo grows fast. Moreover, bamboo fiber is eco-friendly as it can be disposed by incineration instead of landfilling as in the case of inorganic fiber such as glass fiber.

When using bamboo fiber as a papermaking material, it is desirable to use bamboo fiber obtained from bamboos aged one year or older. In general, bamboos grow in 50 days after birth and then grow to stabilize its substance, and it is possible to obtain stable substance after about one year or more passes. Accordingly, it is possible to obtain a desired characteristic for an acoustic member. However, no matter how fast-growing bamboos are, if logging within the first year after birth is continued, the bamboo forest cannot grow stably and the bamboo ecosystem may possibly be disturbed.

It is desirable that an amount of bamboo fiber added to speaker voice coil bobbin 201 be 70 wt % or smaller. If the amount of bamboo fiber is 70 wt % or smaller, it is possible to obtain a voice coil bobbin having high rigidity and a high internal loss, and therefore it is possible to obtain a voice coil bobbin capable of producing rich sound of high acoustic quality.

On the other hand, if the amount of bamboo fiber added to speaker voice coil bobbin 201 is greater than 70 wt %, an amount that metal hydroxide is blended relatively decreases, and it is not possible to obtain desired flame retardancy.

Fiber that is beat to a degree of beating based on Canadian standard freeness ranges from 200 ml to 700 ml inclusive has rigidity suitable as a framework, and less susceptible to poor dispersion during papermaking. Here, if the degree of beating based on Canadian standard freeness is lower than 200 ml, speed of water filtration during papermaking reduces, and productivity significantly decreases.

On the other hand, if the degree of beating based on Canadian standard freeness is higher than 700 ml, a magnitude of entanglement between fibers decreases, and it is difficult to obtain a desired effect. Examples of a method of refining bamboo fiber include a disk refiner and a beater.

If the bamboo fiber is natural fiber having a fiber length from 0.8 mm to 3 mm inclusive, a reinforcing effect as a framework can be enough exhibited, and it is possible to reduce paper-making unevenness when mixed. Here, if the fiber length of the bamboo fiber is shorter than 0.8 mm, the magnitude of entanglement between fibers becomes insufficient and strength of a papermade preform is not sufficient, and it is not possible to obtain a sufficient characteristic.

Further, when mixing metal hydroxide, if the fiber length is short, a proportion of metal hydroxide fixed to the fiber becomes lower, and thus the flame retardancy decreases. On the other hand, if the fiber length of the bamboo fiber is longer than 3 mm, poor dispersion occurs when mixing, often resulting in reduced dispersibility and poor appearance of a molding product.

By molding speaker voice coil bobbin 201 so as to have a density from 0.30 g/cm³ to 0.90 g/cm³ inclusive, it is possible to mold speaker voice coil bobbin 201 without fear of damaging softness and lightness that paper originally has. Here, if the density of speaker voice coil bobbin 201 is smaller than 0.30 g/cm³, the strength significantly reduces and therefore an abnormal noise such as flutter echo in a high-frequency area is easily produced due to insufficient strength.

On the other hand, if the density of speaker voice coil bobbin 201 is greater than 0.90 g/cm³, the specific gravity becomes as much as that of a resin diaphragm, and therefore it is not possible to exhibit superiority in lightness as a feature of the paper voice coil bobbin, often resulting in deterioration of the characteristic such as reduction of the sound pressure.

If an amount of content of lignin in the bamboo fiber is 25 wt % or smaller, it is possible to achieve acoustic quality of rich sound due to a high internal loss of lignin. On the other hand, if the amount of content of lignin is greater than 25 wt %, adhesion between the bamboo fibers is prevented as a surface of the bamboo fiber contains too much lignin, and it is difficult to mold a voice coil bobbin due to insufficient strength when molding as a voice coil bobbin.

Furthermore, as means for effectively improving the acoustic quality, it is desirable to add bamboo fiber beat to the microfibrillated state as a subordinate material. It is desirable that a proportion of an additive amount of the bamboo fiber beat to the microfibrillated state to the bamboo fiber as a whole be from 5 wt % to 20 wt % inclusive.

If the proportion of the additive amount of the bamboo fiber beat to the microfibrillated state ranges from 5 wt % to 20 wt % inclusive, it is possible to obtain a reinforcing effect effective for a binder between fibers.

If the proportion of the additive amount of the bamboo fiber beat to the microfibrillated state is smaller than 5 wt %, it is not possible to obtain a sufficient reinforcing effect as the additive amount is not enough. On the other hand, if the proportion of the additive amount of the bamboo fiber beat to the microfibrillated state is greater than 20 wt %, dispersion becomes poor during papermaking, and appearance of the voice coil bobbin easily becomes poor.

Further, in general, as water filtration of fiber beat to the microfibrillated state is low, time required until this fiber is dehydrated in a papermaking step becomes extremely long, and this significantly increases the production cost. Therefore, it is desirable that a suitable additive amount of the bamboo fiber beat to the microfibrillated state be from 5 wt % to 20 wt % inclusive.

Further, the size of the bamboo fiber beat to the microfibrillated state is enough fined if its fiber length is 0.8 mm or smaller, and the magnitude of entanglement between fibers is enhanced to obtain a desired reinforcing effect. On the other hand, if the fiber length is greater than 0.8 mm, the bamboo fiber is not sufficiently beat, and the magnitude of entanglement between fibers is insufficient and the reinforcing effect is poor.

Furthermore, it is desirable that the degree of beating of the bamboo fiber fined to the microfibrillated state described above be 200 ml or smaller. If the degree of beating is 200 ml or smaller, it is possible to obtain an extremely high reinforcing effect as compared to normal bamboo fiber, as well as superior cost-effectiveness even with a small additive amount. If the degree of beating is greater than 200 ml, this fiber has a comparable level of characteristic to that of normal bamboo fiber, and it is difficult to obtain a reinforcing effect as microfibril fiber.

Furthermore, it is possible to improve the flame retardancy and adjust the acoustic quality by blending a reinforcing material as needed. As the reinforcing material, inorganic fiber or metallic fiber can also be added as reinforcement fiber and a conditioning material of the acoustic quality.

Examples of the inorganic fiber include glass fiber, carbon fiber, and ceramic fiber. Further, examples of the metallic fiber include stainless steel fiber.

It is desirable that an additive amount of glass fiber be from 5 wt % to 40 wt % inclusive, and it is possible to further improve the flame retardancy of the paper voice coil bobbin by mixing the glass fiber by this additive amount. Further, as the glass fiber is rigid, it is possible to increase the rigidity of the paper voice coil bobbin by mixing.

If the additive amount of the glass fiber is smaller than 5 wt %, it is difficult to obtain such effects as a flame-retardant effect and an increased rigidity. If the additive amount of the glass fiber is greater than 40 wt %, many disadvantages are presented such as the paper-making unevenness, the poor appearance, and an increased specific gravity.

It is desirable that an additive amount of carbon fiber be from 5 wt % to 40 wt % inclusive, and it is possible to further improve the flame retardancy of the paper voice coil bobbin by mixing the carbon fiber by this additive amount. Further, as the carbon fiber is rigid, it is possible to increase the rigidity of the paper voice coil bobbin by mixing.

If the additive amount of the carbon fiber is smaller than 5 wt %, it is difficult to obtain such effects as the flame-retardant effect and the increased rigidity. If the additive amount of the carbon fiber is greater than 40 wt %, many disadvantages are presented such as the paper-making unevenness, the poor appearance, and the increased specific gravity.

It is desirable that an additive amount of ceramic fiber be from 5 wt % to 40 wt % inclusive, and it is possible to further improve the flame retardancy of the paper voice coil bobbin by mixing the ceramic fiber by this additive amount. Further, as the ceramic fiber is rigid, it is possible to increase the rigidity of the paper voice coil bobbin by mixing.

If the additive amount of the ceramic fiber is smaller than 5 wt %, it is difficult to obtain such effects as the flame-retardant effect and the increased rigidity. If the additive amount of the ceramic fiber is greater than 40 wt %, many disadvantages are presented such as the paper-making unevenness, the poor appearance, and the increased specific gravity.

It is desirable that an additive amount of stainless steel fiber be from 5 wt % to 40 wt % inclusive, and it is possible to further improve the flame retardancy of the paper voice coil bobbin by mixing the stainless steel fiber by this additive amount. Further, as the stainless steel fiber is rigid, it is possible to increase the rigidity of the paper voice coil bobbin by mixing.

If the additive amount of the stainless steel fiber is smaller than 5 wt %, it is difficult to obtain such effects as the flame-retardant effect and the increased rigidity. If the additive amount of the stainless steel fiber is greater than 40 wt %, many disadvantages are presented such as the paper-making unevenness, the poor appearance, and the increased specific gravity.

Furthermore, it is also possible to improve the flame retardancy and adjust the acoustic quality by blending a filler. As the filler, it is desirable to add calcium carbonate, talc, mica, or carbonized natural fiber.

It is desirable that an additive amount of calcium carbonate be from 5 wt % to 20 wt % inclusive, and it is possible to further improve the flame retardancy of the paper voice coil bobbin by mixing calcium carbonate by this additive amount. Further, as calcium carbonate is rigid, it is possible to increase the rigidity of the paper voice coil bobbin by mixing.

If the additive amount of calcium carbonate is smaller than 5 wt %, it is difficult to obtain such effects as the flame-retardant effect and the increased rigidity. If the additive amount of calcium carbonate is greater than 20 wt %, many disadvantages are presented such as the paper-making unevenness, the poor appearance, and the increased specific gravity.

It is desirable that an additive amount of talc be from 5 wt % to 20 wt % inclusive, and it is possible to further improve the flame retardancy of the paper voice coil bobbin by mixing talc by this additive amount. Further, as talc is rigid, it is possible to increase the rigidity of the paper voice coil bobbin by mixing.

If the additive amount of talc is smaller than 5 wt %, it is difficult to obtain such effects as the flame-retardant effect and the increased rigidity.

If the additive amount of talc is greater than 20 wt %, many disadvantages are presented such as the paper-making unevenness, the poor appearance, and the increased specific gravity.

It is desirable that an additive amount of mica be from 5 wt % to 20 wt % inclusive, and it is possible to further improve the flame retardancy of the paper voice coil bobbin by mixing mica by this additive amount. Further, as mica is rigid, it is possible to increase the rigidity of the paper voice coil bobbin by mixing.

If the additive amount of mica is smaller than 5 wt %, it is difficult to obtain such effects as the flame-retardant effect and the increased rigidity. If the additive amount of mica is greater than 20 wt %, many disadvantages are presented such as the paper-making unevenness, the poor appearance, and the increased specific gravity.

It is desirable that an additive amount of carbonized natural fiber be from 5 wt % to 20 wt % inclusive, and it is possible to further improve the flame retardancy of the paper voice coil bobbin by mixing the carbonized natural fiber by this additive amount. Further, as the carbonized natural fiber is rigid, it is possible to increase the rigidity of the paper voice coil bobbin by mixing.

If the additive amount of the carbonized natural fiber is smaller than 5 wt %, it is difficult to obtain such effects as the flame-retardant effect and the increased rigidity. If the additive amount of the carbonized natural fiber is greater than 20 wt %, many disadvantages are presented such as the paper-making unevenness, the poor appearance, and the increased specific gravity.

Further, the carbonized natural fiber includes numerous fine pores over its surface, reduction of the specific gravity and an improvement of the internal loss are also expected. Further, it is also possible to improve the flame retardancy and the acoustic quality by combining a colorant, a waterproof agent, an impregnation treatment as the known art.

### Sixth Exemplary Embodiment

Hereinafter, speaker 210 employing speaker voice coil bobbin 201 according to the fifth exemplary embodiment is described.

FIG. 6 is a cross-sectional view of a speaker according to a sixth exemplary embodiment of the present invention.

As illustrated in FIG. 6, in speaker 210, internal magnet type magnetic circuit 205 is configured by sandwiching magnetized magnet 202 between upper plate 203 and yoke 204.

Frame 207 is coupled to yoke 204 of magnetic circuit 205. To a periphery portion of frame 207, an outer circumference of speaker diaphragm 208 is adhered via edge 209.

Then, one end of the voice coil is coupled to a center portion of speaker diaphragm 208, and the other end is coupled to magnetic gap 206 of magnetic circuit 205 so as to be fitted therein.

Here, speaker voice coil bobbin 201 is configured such that a material containing metal hydroxide by at least an amount of 30 wt % or greater is formed into a sheet shape by paper making and molded into a shape of a voice coil bobbin.

The above describes the speaker having an internal magnet type magnetic circuit. However, the present invention is not limited to such an example, and can be applied to a speaker having an external magnet type magnetic circuit.

With such a configuration, it is possible to provide a speaker capable of achieving flame retardancy, high acoustic quality, and cost reduction.

### Seventh Exemplary Embodiment

Hereinafter, mini component system 214 employing speaker 210 according to the sixth exemplary embodiment is described.

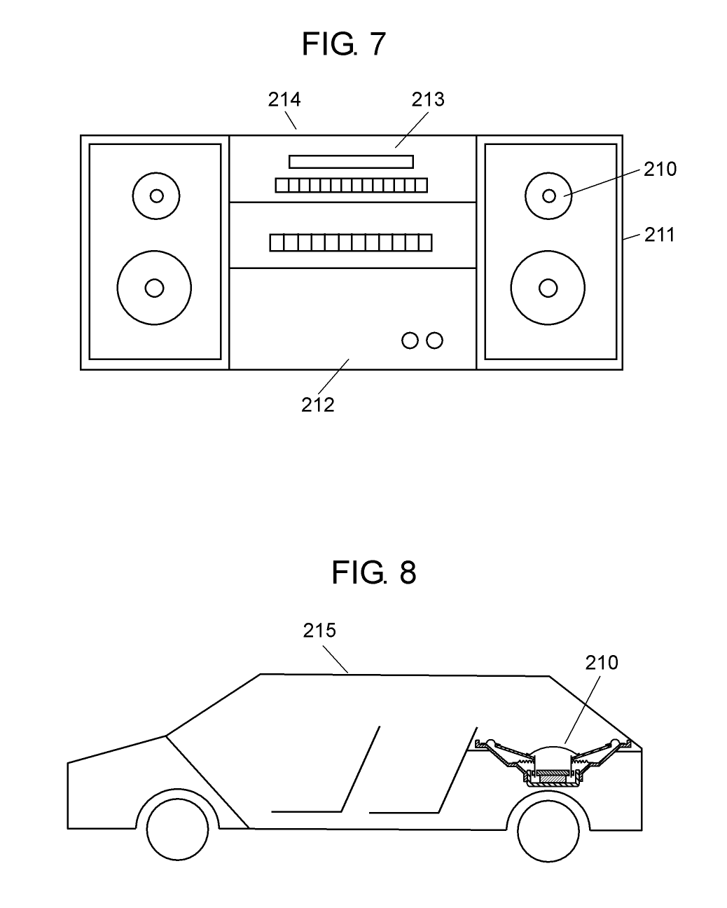

FIG. 7 is an external view of audio mini component system 214 as an electronic apparatus having speaker 210 built-in.

As illustrated in FIG. 7, mini component system 214 according to this embodiment includes enclosure 211 having speaker 210 assembled, amplifier 212 as means for amplifying electric signals inputted to speaker 210, and player 213 configured to output a source inputted to amplifier 212.

Here, the bobbin used in a voice coil of speaker 210 is configured such that a material containing metal hydroxide by at least an amount of 30 wt % or greater is formed into a sheet shape by paper making and molded into a shape of a voice coil bobbin.

With such a configuration, mini component system 214 achieves flame retardancy, high acoustic quality, and cost reduction that cannot be conventionally achieved.

### Eighth Exemplary Embodiment

Hereinafter, a vehicle having speaker 210 according to the sixth exemplary embodiment built-in is described.

FIG. 8 is a cross-sectional view of vehicle 215 having speaker 210 built-in.

As illustrated in FIG. 8, vehicle 215 according to this embodiment utilizes speaker 210 as a component of car navigation or car audio sets by assembling speaker 210 to a rear tray or a front panel.

Here, the bobbin used in a voice coil of speaker 210 is configured such that a material containing metal hydroxide by at least an amount of 30 wt % or greater is formed into a sheet shape by paper making and molded into a shape of a voice coil bobbin.

With such a configuration, vehicle 215 achieves flame retardancy and high acoustic quality that cannot be conventionally achieved, and it is possible to contribute to its safety, comfort, and cost reduction.

### INDUSTRIAL APPLICABILITY

A speaker component such as a speaker diaphragm and a speaker voice coil bobbin and a speaker according to the present invention can be applied to an electronic apparatus of video and acoustic equipment or an information and communications device for which all of flame retardancy, high acoustic quality, and cost reduction are required, as well as to a vehicle such as an automobile.

### REFERENCE MARKS IN THE DRAWINGS

101, 208 speaker diaphragm

101A, 201A natural fiber

101B, 201B metal hydroxide

102, 202 magnet

103, 203 upper plate

104, 204 yoke

105, 205 magnetic circuit

106, 206 magnetic gap

107, 207 frame

108 voice coil

109, 209 edge

110, 210 speaker

111, 211 enclosure

112, 212 amplifier

113, 213 player

114, 214 mini component system

115, 215 vehicle

201 speaker voice coil bobbin

1. A speaker component manufactured by a papermaking method, the speaker component comprising:
metal hydroxide by at least an amount of 30 wt % or greater.

2. The speaker component according to claim 1, further comprising:
a non-wood material.

3. The speaker component according to claim 2, wherein
the non-wood material is bamboo fiber.

4. The speaker component according to claim 3, wherein
the bamboo fiber is obtained from bamboos aged one year or older.

5. The speaker component according to claim 3, wherein
an amount of the bamboo fiber is 70 wt % or smaller.

6. The speaker component according to claim 3, wherein
a degree of beating of the bamboo fiber based on Canadian standard freeness ranges from 200 ml to 700 ml inclusive.

7. The speaker component according to claim 3, wherein
a fiber length of the bamboo fiber ranges from 0.8 mm to 3 mm inclusive.

8. The speaker component according to claim 3, wherein
a density ranges from 0.30 g/cm³ to 0.90 g/cm³ inclusive.

9. The speaker component according to claim 3, wherein
an amount of content of lignin in the bamboo fiber is 25 wt % or smaller.

10. The speaker component according to claim 3, wherein
the bamboo fiber includes bamboo fiber fined to a microfibrillated state as a subordinate material, and an amount of content of the subordinate material in the bamboo fiber as a whole ranges from 5 wt % to 20 wt % inclusive.

11. The speaker component according to claim 10, wherein
a fiber length of the bamboo fiber fined to the microfibrillated state is 0.8 mm or smaller.

12. The speaker component according to claim 10, wherein
a degree of beating of the bamboo fiber fined to the microfibrillated state is 200 ml or smaller.

13. The speaker component according to claim 1, further comprising:
a reinforcing material.

14. The speaker component according to claim 1, wherein
the speaker component is a speaker diaphragm.

15. The speaker component according to claim 1, wherein
the speaker component is a speaker voice coil bobbin.

16. A speaker comprising:
a speaker diaphragm;
a frame coupled to an outer circumference portion of the speaker diaphragm and to a magnetic circuit; and
a voice coil coupled to the speaker diaphragm and movably disposed in a magnetic gap defined by the magnetic circuit, wherein
the speaker diaphragm is manufactured by a papermaking method and includes metal hydroxide by at least an amount of 30 wt % or greater.

17. A speaker comprising:
a speaker diaphragm;
a frame coupled to an outer circumference portion of the speaker diaphragm and to a magnetic circuit; and
a voice coil coupled to the speaker diaphragm and movably disposed in a magnetic gap defined by the magnetic circuit, wherein
the voice coil includes a speaker voice coil bobbin manufactured by a papermaking method and including metal hydroxide by at least an amount of 30 wt % or greater.

18. An electronic apparatus at least comprising:
a speaker; and
an amplifier for amplifying electric signals inputted to the speaker, wherein
the speaker at least includes:
a speaker diaphragm manufactured by a papermaking method and including metal hydroxide by at least an amount of 30 wt % or greater;
a frame coupled to an outer circumference portion of the speaker diaphragm and to a magnetic circuit; and
a voice coil coupled to the speaker diaphragm and movably disposed in a magnetic gap defined by the magnetic circuit.

19. An electronic apparatus at least comprising:
a speaker; and
an amplifier for amplifying electric signals inputted to the speaker, wherein
the speaker at least includes:
a speaker diaphragm;
a frame coupled to an outer circumference portion of the speaker diaphragm and to a magnetic circuit; and
a voice coil coupled to the speaker diaphragm and movably disposed in a magnetic gap defined by the magnetic circuit, and
the voice coil includes a speaker voice coil bobbin manufactured by a papermaking method and including metal hydroxide by at least an amount of 30 wt % or greater.

20. A moving means comprising:
a speaker including:
a speaker diaphragm manufactured by a papermaking method and including metal hydroxide by at least an amount of 30 wt % or greater;
a frame coupled to an outer circumference portion of the speaker diaphragm and to a magnetic circuit; and
a voice coil coupled to the speaker diaphragm and movably disposed in a magnetic gap defined by the magnetic circuit.

21. A moving means comprising:
a speaker including:
a speaker diaphragm;
a frame coupled to an outer circumference portion of the speaker diaphragm and to a magnetic circuit; and
a voice coil coupled to the speaker diaphragm and movably disposed in a magnetic gap defined by the magnetic circuit, and
the voice coil includes a speaker voice coil bobbin manufactured by a papermaking method and including metal hydroxide by at least an amount of 30 wt % or greater.
